(19) United States
(12) Patent Application Publication
(10) Pub. No.: US 2026/0223639 A1
(43) Pub. Date: Jul. 30, 2026

(54) MANUFACTURING METHOD OF SEMICONDUCTOR DEVICE

(71) Applicant: Alliance Material Co., Ltd., Hsinchu County (TW)

(72) Inventors: Hsueh Chung Wu, Hsinchu County (TW); Chun Fa Chen, Hsinchu County (TW); Chi Hua Huang, Hsinchu County (TW); Chin Kai Lin, Hsinchu County (TW); Chen Ju Lee, Hsinchu County (TW); Shi Rou Xie, Hsinchu County (TW); Xuan You Chen, Hsinchu County (TW); Kuan Chun Hu, Hsinchu County (TW)

(73) Assignee: Alliance Material Co., Ltd., Hsinchu County (TW)

(21) Appl. No.: 19/428,335

(22) Filed: Dec. 22, 2025

(30) Foreign Application Priority Data
Jan. 24, 2025 (TW) 114103270

(51) Int. Cl. H10P 72/70

(52) U.S. Cl. CPC H10P 72/744; H10P 72/7402; H10P 72/7432

(57) ABSTRACT

A manufacturing method of a semiconductor device includes forming a debonding material layer on a first release layer; performing a first heating process to convert the debonding material layer from a liquid state to a solid state to form a first film structure; forming an adhesive layer on a second release layer to form a second film structure; assembling the first film structure and the second film structure into a film component; attaching the film component to a process component; performing a second heating process on the film component; and performing a laser process to remove the debonding material layer.

### CROSS-REFERENCE TO RELATED APPLICATION

This application claims the priority benefit of Taiwan application serial no. 114103270, filed on Jan. 24, 2025. The entirety of the above-mentioned patent application is hereby incorporated by reference herein and made a part of this specification.

### BACKGROUND

### Technical Field

The disclosure relates to a manufacturing method of a semiconductor device.

### Description of Related Art

In the process of manufacturing semiconductor devices, during stages such as wafer thinning, backside support, and circuit fabrication (e.g., sputtering, electroplating, exposure, development, etching, and passivation), a coating process is often employed to directly apply debonding materials onto the process components to serve as temporary functional elements. However, this coating process is associated with issues such as lower product yield, longer manufacturing time, and higher manufacturing costs.

### SUMMARY

A manufacturing method of a semiconductor device, which may effectively improve product yield, shorten manufacturing time and reduce manufacturing costs, is provided in the disclosure.

A manufacturing method of a semiconductor device according to the disclosure includes the following operation. A debonding material layer is formed on a first release layer. A first heating process is performed to convert the debonding material layer from a liquid state to a solid state to form a first film structure. An adhesive layer is formed on a second release layer to form a second film structure. The first film structure and the second film structure are assembled into a film component. The film component is attached to the process component. A second heating process is performed on the film component. A laser process is performed to remove the debonding material layer.

In one embodiment of the disclosure, a temperature of the first heating process is lower than a temperature of the second heating process.

In one embodiment of the disclosure, a heating temperature range of the first heating process is between 60° C. and 200° C., and a heating time range of the first heating process is between 10 seconds (sec) and 120 seconds (sec).

In one embodiment of the disclosure, a heating temperature range of the second heating process is between 200° C. and 300° C., and a heating time range of the second heating process is between 10 minutes (min) and 60 minutes (min).

In one embodiment of the disclosure, an energy density of the laser process is between 1 watt (W) and 6 watts (W).

In one embodiment of the disclosure, a wavelength of the laser process is 355 nanometers or 532 nanometers.

In one embodiment of the disclosure, the debonding material layer is formed by a micro-gravure process.

In one embodiment of the disclosure, attaching the film component to the process component further includes the following operation. The debonding material layer and the first release layer are attached to the process component through the adhesive layer after removing the second release layer. A trimming process is performed on the adhesive layer, the debonding material layer, and the first release layer. The first release layer is removed.

In one embodiment of the disclosure, edges of the adhesive layer, edges of the debonding material layer, and edges of the process component are aligned after performing the trimming process.

In one embodiment of the disclosure, the process component is a square glass wafer.

Based on the above, the temporary functional component (film component) manufactured through step design in the manufacturing method of a semiconductor device of the disclosure has advantages such as higher ease of use, better film uniformity and lower manufacturing cost. Therefore, when it is attached to the process component, the product yield may be effectively improved, the manufacturing time may be shortened and the manufacturing cost may be reduced.

In order to make the above-mentioned features and advantages of the disclosure comprehensible, embodiments accompanied with drawings are described in detail below.

### BRIEF DESCRIPTION OF THE DRAWINGS

FIG. 1, FIG. 2, FIG. 3, FIG. 4 and FIG. 5 are partial cross-sectional schematic diagrams of a manufacturing method of a semiconductor device according to an embodiment of the disclosure.

FIG. 6 is a partial side view of the forming method of the debonding material layer of FIG. 1.

### DETAILED DESCRIPTION OF DISCLOSED EMBODIMENTS

The disclosure is more fully described with reference to the drawings of this embodiment. However, the disclosure may be embodied in various different forms and should not be limited to the embodiments set forth herein only. The thickness, dimension, or size of layers or regions in the drawings may be exaggerated for clarity. The same or similar reference numerals denote the same or similar elements, and the descriptions are not repeated in the following paragraphs.

Unless otherwise stated, the term “between” used in this specification to define numerical ranges is intended to cover the range equal to and between the endpoint values. For example, a size range between a first value and a second value means that the size range may cover the first value, the second value, and any value between the first value and the second value.

Unless otherwise defined, all terms (including technical and scientific terms) used herein have the same meaning as commonly understood by one of ordinary skill in the art to which this disclosure belongs.

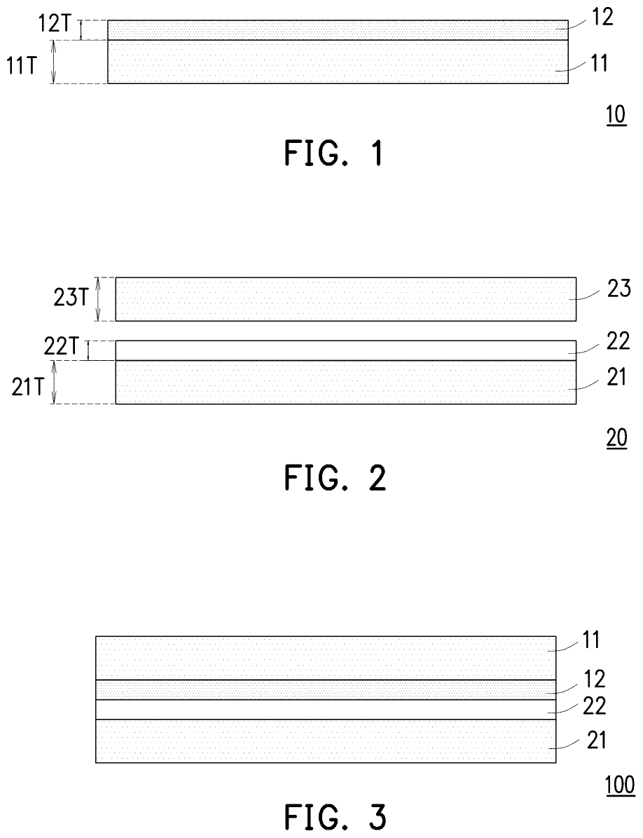

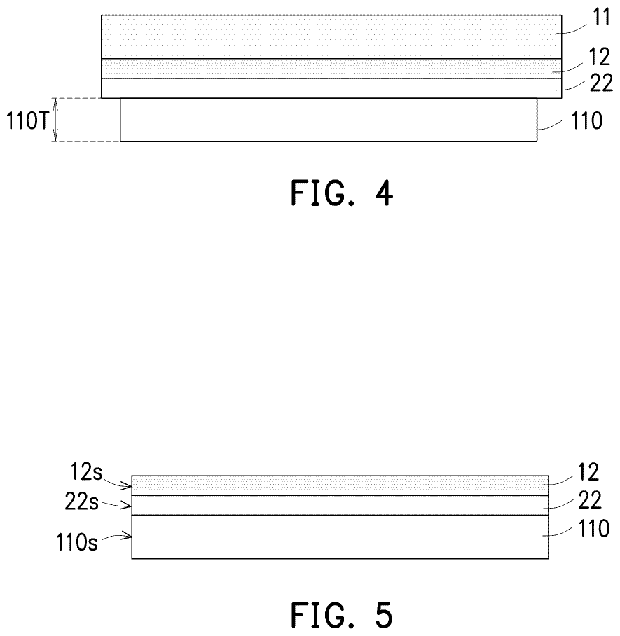

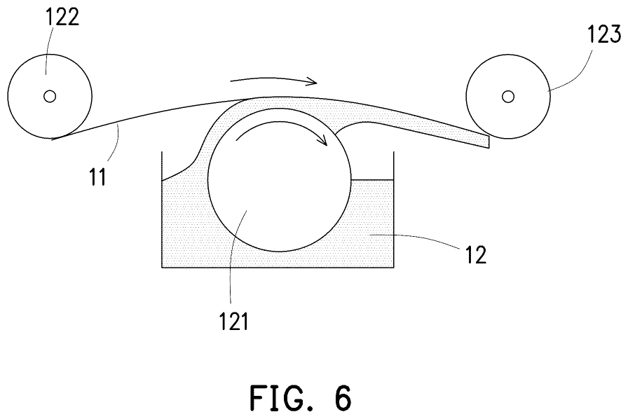

FIG. 1, FIG. 2, FIG. 3, FIG. 4 and FIG. 5 are partial cross-sectional schematic diagrams of a manufacturing method of a semiconductor device according to an embodiment of the disclosure. FIG. 6 is a partial side view of the forming method of the debonding material layer of FIG. 1.

Referring to FIG. 1, a first release layer 11 is provided, thereby facilitating the subsequent transfer of a debonding material layer 12. A thickness 11T of the first release layer 11 may range between 75 micrometers (μm) and 100 micrometers. Here, the material of the first release layer 11 may be polyethylene terephthalate (PET), polyolefins (PO), release paper or the like, and the release force of the first release layer 11 may be determined according to the actual material selected, which is not limited by the disclosure.

Next, the debonding material layer 12 may be formed on the first release layer 11, in which the debonding material layer 12 is suitable for debonding in a laser process. In this embodiment, the debonding material layer 12 may be in a liquid state when it is first formed. Therefore, after its formation, a first heating process (soft baking) may be further performed to remove the organic solvent in the debonding material layer 12, such that the debonding material layer 12 may convert from a liquid state to a solid state, thereby forming a first film structure 10. A heating temperature of the first heating process may be less than or equal to 180° C., for example, the heating temperature range of the first heating process is between 60° C. and 200° C., so as to reduce the probability of heat having an adverse effect on the first release layer 11. Furthermore, A heating time of the first heating process may be less than or equal to 2 minutes, for example, the heating time of the first heating process is between 10 seconds and 120 seconds, so as to ensure that the drying effect is achieved, but the disclosure is not limited thereto.

In some embodiments, the material of the debonding material layer 12 may be composed of a diamine monomer, a dianhydride monomer, and an organic solvent. Therefore, after performing the first heating process to remove the organic solvent, the material may be converted into polyamic acid (PAA). Here, the composition ratio of diamine monomer, dianhydride monomer and organic solvent may be determined according to the actual design requirements, which is not limited by the disclosure. As long as they may subsequently be formed into a polyimide film that may be debonded by laser, they fall within the protective scope of this disclosure.

In some embodiments, the molar ratio of the diamine monomer to the dianhydride monomer is 1:1 to 1:1.07, for example, the molar ratio of the diamine monomer to the dianhydride monomer is 1:1.02 to 1:1.05. If the proportion of diamine monomer is too low or the proportion of dianhydride monomer is too high (e.g., the molar ratio of diamine monomer to dianhydride monomer is 1:2.5, 1:3, or higher), the adhesion of the debonding material layer 12 may be reduced. Alternatively, if the proportion of diamine monomer is too low or the proportion of dianhydride monomer is too high (e.g., the molar ratio of diamine monomer to dianhydride monomer is 1:2.5, 1:3, or higher), the chemical resistance of the debonding material layer 12 may be reduced. Alternatively, if the proportion of diamine monomer is too high or the proportion of dianhydride monomer is too low (e.g., the molar ratio of diamine monomer to dianhydride monomer is 2:1 or lower), the heat resistance of the debonding material layer 12 may be reduced.

In one embodiment, the molar ratio of the diamine monomer to the dianhydride monomer is 1:1.02 to 1:1.05.

The following provides a detailed description of the possible embodiments of the various components of the material used in the debonding material layer 12 of the disclosure.

### <Diamine Monomer>

In some embodiments, the diamine monomer may include an aromatic diamine, in which the aromatic diamine may include 4,4′-(9-fluorenylidene)dianiline (FDA; CAS: 15499-84-0), N,N,N′,N′-tetra(paminophenyl)-p-phenylenediamine (CAS: 3283-07-6), p-phenylenediamine (PDA), 3,4′-oxydianiline (3,4′-ODA), 4,4′-oxydianiline (4,4′-ODA), 4,4′-dichlorodiphenyl sulfone (4,4′-DDS; CAS: 80-07-9), 3,5-diamino-1,2,4-triazole (DATA; CAS: 1455-77-2), N,N′-(4,4′-(9H-fluorene-9,9-diyl)bis(4,1-phenylene))bis(4-aminobenzamide) (FDA-ADA); as shown in the following Formula 1), and one of the groups composed of its mixture.

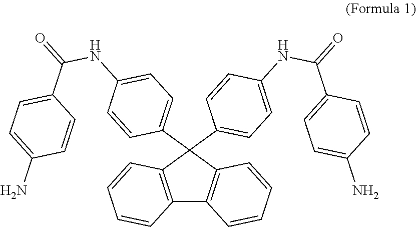 [SMILES: Nc1ccc(C(=O)Nc2ccc(C3(c4ccc(NC(=O)c5ccc(N)cc5)cc4)c4ccccc4-c4ccccc43)cc2)cc1]

### <Dianhydride Monomer>

In some embodiments, the dianhydride monomer of the temporary adhesive composition may include aromatic dianhydrides, in which the aromatic dianhydrides may include those selected from N,N′-(9H-fluoren-9-ylidenedi-4,1-phenylene)bis [1,3-dihydro-1,3-dioxo-5-isobenzofurancarboxamide] (FDA-ATA; CAS: 867350-98-9), cyclobutane-1,2,3,4-tetracarboxylic dianhydride (CBDA), biphenyl-tetracarboxylic acid dianhydride (BPDA), and one of the groups composed of its mixture.

### <Organic Solvent>

In some embodiments, the organic solvent used for imidization may include ketones selected from y-butyrolactone, 1,3-dimethyl-imidazolidineone, methyl ethyl ketone, cyclohexanone, cyclopentanone, 4-hydroxy-4-methyl-2-pentanoneor the like; aromatic hydrocarbons such as toluene, xylene, and tetramethylbenzene; glycol ethers such as ethylene glycol monoethyl ether, ethylene glycol monomethyl ether, ethylene glycol monobutyl ether, diethylene glycol monoethyl ether, diethylene glycol monomethyl ether, diethylene glycol monobutyl ether, propylene glycol monomethyl ether, propylene glycol monoethyl ether, dipropylene glycol diethyl ether, triethylene glycol monoethyl ether or the like; ethyl acetate, butyl acetate, ethylene glycol monoethyl ether acetate, ethylene glycol monobutyl ether acetate, diethylene glycol monoethyl ether acetate, dipropylene glycol monomethyl ether acetate, ethanol, propanol, ethylene glycol, propylene glycol, carbitol, dimethylacetamide (DMAc), N,N-diethylacetamide, dimethylformamide (DMF), diethylformamide (DEF), N-methylpyrrolidone (NMP), N-ethylpyrrolidone (NEP), 1,3-dimethyl-2-imidazolidinedion, N,N-Dimethyl-2-methoxyacetamide, dimethyl sulfoxide, pyridine, dimethyl sulfone, hexamethylphosphoramide, tetramethylurea, N-methylcaprolactam, tetrahydrofuran, m-dioxane, p-dioxane, 1,2-dimethoxyethane, bis(2-methoxyethyl) ether, 1,2-bis(2-methoxyethoxy) ethane, bis [2-(2-methoxyethoxy)] ether, and one of the groups composed of its mixture.

In some embodiments, salts may be added to the organic solvent. Salts may include alkali metal salts or alkaline earth metal salts and one of the groups composed of its mixture. The amount of salt added is, for example, less than or equal to 50 wt % based on the total weight of the solvent.

In this embodiment, the thickness 12T of the debonding material layer 12 may be less than 1 micrometer, and for example, it may be greater than 0.1 micrometer. At this thickness, the debonding energy required for subsequent laser processing may be reduced. In this way, the probability of thermal damage to the surface of the process component 110 (as shown in FIG. 5) may be reduced, but the disclosure is not limited thereto.

In some embodiments, as shown in FIG. 6, the thickness 12T of the debonding material layer 12 may be achieved by a micro-gravure process. In this process, the specific operation method is to place the liquid material of the debonding material layer 12 (viscosity, for example, less than 50 cps) in a tank, and then coat the material onto the surface of the first release layer 11 by the drive of the middle roller 121 and the two side rollers 122 and 123. In this way, compared with the gravure process of upper and lower roller coating, a thinner and more uniform thickness may be coated, and the film surface formed will also be smoother. Therefore, the debonding material layer 12 formed by the micro-gravure process may be more competitive in the product, but the disclosure is not limited thereto.

Referring to FIG. 2, an adhesive layer 22 is formed on the second release layer 21 to form the second film structure 20. The adhesive layer 22 may be formed directly on the second release layer 21 by coating, printing or other suitable processes, and the thickness 22T of the adhesive layer 22 may range between 5 micrometers and 10 micrometers. Here, the adhesive layer 22 may employ any suitable heat-resistant adhesive material, and the disclosure is not limited thereto. Some possible specific examples will be listed below.

In some embodiments, the adhesive layer 22 includes an adhesive composition. The adhesive composition includes an appropriate proportion of acrylic curable compounds and functional monomers.

In some embodiments, the monomer of an acrylic curable compound may be a compound having a (meth)acrylate group. For example, compounds with a (meth)acrylate group may include those selected from methyl (meth)acrylate, ethyl (meth)acrylate, n-propyl (meth)acrylate, isopropyl (meth)acrylate, n-butyl (meth)acrylate, t-butyl (meth)acrylate, sec-butyl (meth)acrylate, pentyl(meth)acrylate, 2-ethylhexyl (meth)acrylate, 2-ethylbutyl(meth)acrylate, n-octyl (meth)acrylate, isooctyl (meth)acrylate, isononyl (meth)acrylate, lauryl (meth)acrylate, tetradecyl(meth)acrylate, acrylic acid, methacrylic acid, 2-(meth)acryloyloxyacetic acid, 3-(meth)acryloyloxy propyl acid, 4-(meth)acryloyloxybutyric acid, 2-hydroxyethyl (meth)acrylate, 2-hydroxypropyl (meth)acrylate, 4-hydroxybutyl (meth)acrylate, 6-hydroxyhexyl(meth)acrylate, 8-hydroxyoctyl(meth)acrylate, 2-hydroxy ethylene glycol (meth)acrylate, or 2-hydroxy propylene glycol (meth)acrylate, and one of the groups formed by the above combinations.

In some embodiments, the aforementioned acrylic curable compound may be an acrylic photocurable compound, and the adhesive composition may further include a photoinitiator. For example, photoinitiators include organic photoinitiators such as oximes (e.g., acyloxime, ketoneoxime, or other oximes), benzoin and its derivatives (e.g., benzoin, benzoin dimethyl ether, benzoin ethyl ether, benzoin isopropyl ether, benzoin butyl ether), benzil, alkyl phenyl ketones (e.g., a-hydroxyalkyl (HAPK)), acylphosphine oxides (e.g., alkyl diacetylphosphine oxide), benzophenones, thioxanthen-9-one; or cationic photoinitiators such as diazonium salts, diaryliodonium salts, triarylsulfonium salts, alkylsulfonium salts, aromatic iron salts, sulfonyl ketones, and triarylsiloxanes; or a derivative or a combination thereof.

In some embodiments, the functional monomer may be a crosslinking agent, a heat-resistant monomer, and/or a diluting monomer.

In some embodiments, the adhesive composition is free of organic solvents. The aforementioned organic solvents, such as n-hexane, toluene, xylene, and methyl isobutyl ketone, may be used individually or in various combinations. In this way, the adhesive layer 22 may reduce process contamination in semiconductor manufacturing processes (e.g., baking, heated deposition, exposure and development, or other semiconductor processes with high temperature or low pressure).

In some embodiments, the adhesive layer 22 is, for example, a pressure-sensitive adhesive. For example, the material of the adhesive layer 22 includes acrylic resin, polyurethane resin, polysiloxane resin, a combination of the above materials, or other suitable polymer materials.

In some embodiments, the adhesive layer 22 may include a photosensitive material, and the adhesive layer 22 reduces its adhesive strength after being exposed to light (e.g., ultraviolet light), allowing it to be debonded by light exposure in subsequent processes. Alternatively, the adhesive layer 22 may include a thermosetting material, and the adhesive layer 22 reduces its adhesive strength after being heated, allowing it to be debonded by heating in subsequent processes. Alternatively, the adhesive layer 22 may include a cold-release material, and the adhesive layer 22 reduces its adhesive strength when cooled to below the glass transition temperature, allowing it to be debonded by cooling in subsequent processes.

The adhesive layer 22 is suitable for bonding the debonding material layer 12 to the adherend (e.g., a process component). The adhesive layer 22 is bonded to other materials by means of physical adsorption, diffusion, electrostatic adsorption, mechanical interlocking, and chemical bonding.

In some embodiments, the raw materials of the adhesive layer 22 include oligomers, monomers, initiators, and additives. For example, the cured adhesive layer 22 includes acrylic resin or other suitable materials. In some embodiments, the oligomer includes polyester acrylate, polyurethane acrylate, polyether acrylate, or a combination thereof.

In some embodiments, in the raw material of adhesive layer 22, the weight ratio of the aforementioned monomer ranges from 20 wt % to 50 wt %, such as 20 wt %, 30 wt %, 40 wt %, 50 wt %, or any range within 20 wt % to 50 wt %. In some embodiments, the monomer includes a monofunctional monomer, a difunctional monomer, a multifunctional monomer, or a combination thereof.

In some embodiments, the monofunctional monomer is, for example, isodecyl acrylate (IDA), tetrahydrofurfuryl acrylate (THFA), isobornyl acrylate (IBOA), or 2-phenoxyethyl acrylate (PHEA). The chemical structures of isodecyl acrylate, tetrahydrofurfuryl acrylate, isobornyl acrylate, and 2-phenoxyethyl acrylate are shown in Formula 2, Formula 3, Formula 4, and Formula 5, respectively.

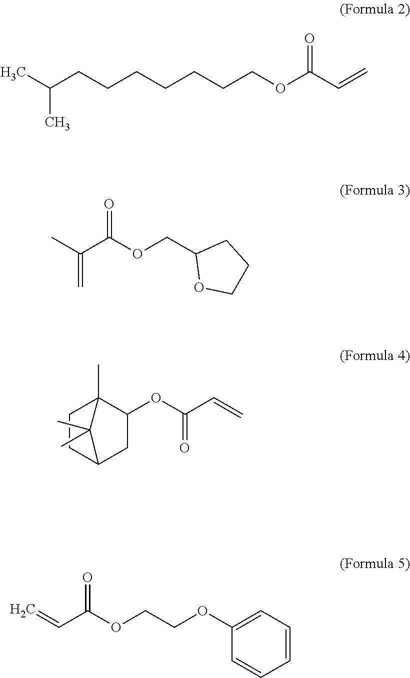

In some embodiments, the difunctional monomer is, for example, hexanediol diacrylate (HDDA) or polyethylene glycol (600)diacrylate (PEG (600) DA). The chemical structures of hexanediol diacrylate and polyethylene glycol (600)diacrylate are shown in Formula 6 and Formula 7, respectively.

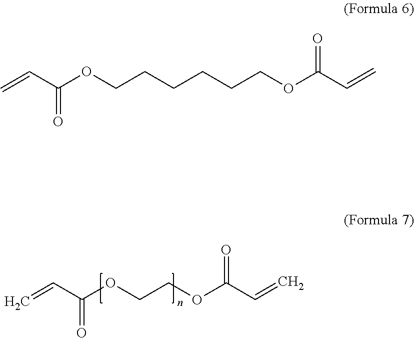

In some embodiments, the multifunctional monomer is, for example, trimethylolpropane triacrylate (TMPTA) or dipentaerythritol hexaacrylate (DPHA). The chemical structures of trimethylolpropane triacrylate and dipentaerythritol hexaacrylate are shown in Formula 8 and Formula 9, respectively.

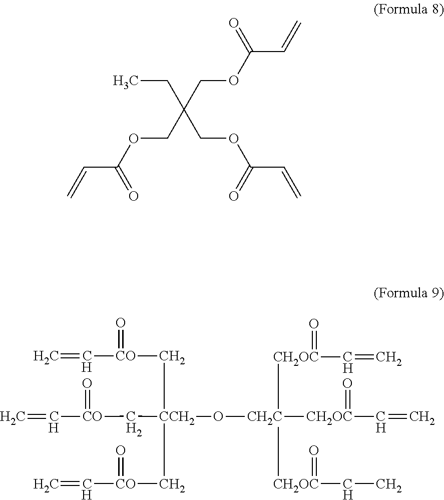

The initiator in the raw material of adhesive layer 22 is suitable for initiating polymerization and crosslinking reactions. For example, one or more photoinitiators may be used to induce polymerization and crosslinking reactions between monomers and oligomers. In some embodiments, the photoinitiator includes a free radical photoinitiator. In some embodiments, in the raw material of adhesive layer 22, the photoinitiator has a weight ratio of less than or equal to 10 wt %, for example, 9 wt %, 8 wt %, 7 wt %, 6 wt %, 5 wt %, 4 wt %, 3 wt %, 2 wt %, 1 wt %, or any value less than 10 wt %. In some embodiments, the photoinitiator is suitable for absorbing ultraviolet light to initiate a polymerization reaction.

In some embodiments, the polyester acrylate resin, polyurethane acrylate resin, or polyether acrylate resin uses a free radical photoinitiator, such as 1-hydroxycyclohexyl phenyl ketone or phenyl bis(2,4,6-trimethylbenzoyl)-phosphine oxide, with the chemical structures shown in Formula 10 and Formula 11, respectively.

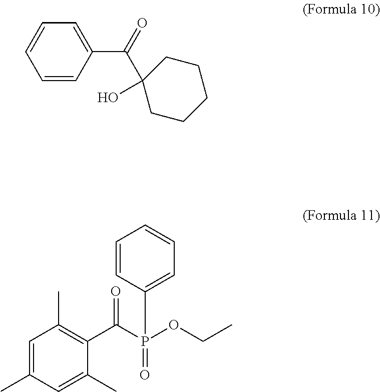 [SMILES: O=C(c1ccccc1)C1(O)CCCCC1 ; CCOP(=O)(C(=O)c1c(C)cc(C)cc1C)c1ccccc1]

In some embodiments, the raw materials for adhesive layer 22 also include additives. Additives include, for example, surfactants, stabilizers, dyes, solvents, or other materials. In some embodiments, the additives include conductive particles, conductive fibers, conductive polymers or other suitable conductive materials, such that the adhesive layer 22 has an antistatic function. In some embodiments, the additive includes a difunctional acrylic oligomer (e.g., an aliphatic urethane diacrylate oligomer), which may improve the crosslinking properties of the adhesive layer 22, further enhance the chemical resistance and heat resistance of the adhesive layer 22, and reduce the problem of residual adhesive after removing the adhesive layer 22. In some embodiments, the additive includes a difunctional monomer (e.g., ethoxylated bisphenol A diacrylate, 1,6-hexanediol diacrylate, or a combination thereof), which may further enhance the crosslinking strength of the adhesive layer 22.

In this embodiment, the adhesive layer 22 may also be in the form of double-sided tape, that is, it may be sandwiched between the second release layer 21 and the third release layer 23. When it is intended for use, the third release layer 23 is removed to form the second film structure 20. The thickness 21T of the second release layer 21 may range between 0.025 mm and 0.1 mm (e.g., 50 micrometers), and the thickness 22T of the third release layer 23 may range between 0.025 mm and 0.1 mm (e.g., 38 micrometers). The materials of the second release layer 21 and the third release layer 23 may be similar to those of the first release layer 11, and details are not repeated herein.

Referring to FIG. 3, the first film structure 10 and the second film structure 20 are assembled into a film component 100. In this embodiment, after assembly, the debonding material layer 12 and the adhesive layer 22 may be sandwiched between the first release layer 11 and the second release layer 21, and the debonding material layer 12 and the adhesive layer 22 may be in direct contact. Accordingly, through the aforementioned step design, a temporary functional component in the intermediate stage (the film component 100 including a solid polyamic acid laser debonding layer 12 and an adhesive layer 22) may be manufactured.

Referring to FIG. 4 and FIG. 5, the film component 100 is attached onto the process component 110. The thickness 110T of the process component 110 may be determined according to the specifications of the semiconductor device to be processed, which is not limited by the disclosure. For example, the thickness 110T of the process component 110 may be a circular glass wafer or a square glass wafer between 0.1 mm and 3.0 mm.

Next, a second heating process (hard baking) may be performed on the film component 100 to imidize (dehydration and cyclization) the debonding material layer 12 into polyimide (PI) to achieve its desired functionality (heat resistance, adhesion, or chemical resistance or the like). The temperature of the first heating process is lower than the temperature of the second heating process. For example, A heating temperature range of the second heating process is between 200° C. and 300° C., and a heating time range of the second heating process is between 10 minutes and 60 minutes, but the disclosure is not limited thereto. Accordingly, the temporary functional component (the film component 100 including a solid polyimide laser debonding layer 12 and an adhesive layer 22) manufactured through the above step design in the semiconductor device manufacturing method of the disclosure has advantages such as higher ease of use, better film uniformity and lower manufacturing cost. Therefore, when it is attached to the process component (by omitting the coating process), the product yield may be effectively improved, the manufacturing time may be shortened and the manufacturing cost may be reduced.

Furthermore, after performing the second heating process, a laser process may be performed to remove the film component 100 (not shown). Since this embodiment has a thinner debonding material layer 12, a smaller debonding energy may be used to reduce the probability of thermal damage to the surface of the process component 110. For example, when the wavelength of the laser process is 355 nanometers or 532 nanometers, the energy density of the laser process is between 1.0 W and 6.0 W. However, the disclosure is not limited thereto. The specific parameters of the laser process may be determined according to the actual design requirements.

On the other hand, since current coating equipment is designed based on circular process components (e.g., circular glass wafers), when it is intended to be used for fan-out panel level packaging (FOPLP), only a square recess may be set within the circular area. Consequently, if the viscosity of the coating liquid is too high, there will be poor coating uniformity. Conversely, if the viscosity of the coating liquid is too low, there will be occurrences of fisheye defect (such as bubbles, volcano pore, poor wetting), and simultaneously, the material may splatter outside the recess, resulting in wastage. Furthermore, this method requires larger drying equipment and the machine must be cleaned after each coating. Also, when the panel size is adjusted, the recess size needs to be adjusted accordingly. Therefore, when the process component 110 is a square glass wafer for fan-out panel level packaging, the film component 100 may avoid the aforementioned problems, thereby possessing greater product competitiveness.

In some embodiments, the film component 100 may be attached to the process component 110 by the following steps. First, as shown in FIG. 4, after removing the second release layer 21, the debonding material layer 12 and the first release layer 11 may be bonded to the process component 110 by the adhesive layer 22. Since the size of the film component 100 in this embodiment is larger than the size of the process component 110, after bonding, a trimming process may be performed on the adhesive layer 22, the debonding material layer 12 and the first release layer 11 such that the edges 12s of the debonding material layer 12, the edges 22s of the adhesive layer 22, and the edges 110s of the process component 110 are aligned. Then, as shown in FIG. 5, the first release layer 11 is removed. However, the disclosure is not limited thereto. In embodiments not shown, it is also possible to pre-cut the film component to match the dimensions of the process component, thus allowing the first release layer 11 to be directly removed after adhering the film component to the process component. Here, since the film component 100 may be trimmed or pre-cut to fit the size of the process component 110, the film component 100 has better flexibility in use.

It should be noted that the above-described process steps may be applied to any stage in the manufacturing method of a semiconductor device that requires temporary functional elements, such as wafer thinning, backside support, and circuit fabrication, the disclosure is not limited thereto.

To sum up, the temporary functional component (film component) manufactured through step design in the manufacturing method of a semiconductor device of the disclosure has advantages such as higher ease of use, better film uniformity and lower manufacturing cost. Therefore, when it is attached to the process component, the product yield may be effectively improved, the manufacturing time may be shortened and the manufacturing cost may be reduced.

Although the disclosure has been described in detail with reference to the above embodiments, they are not intended to limit the disclosure. Those skilled in the art should understand that it is possible to make changes and modifications without departing from the spirit and scope of the disclosure. Therefore, the protection scope of the disclosure shall be defined by the following claims.

What is claimed is:

1. A manufacturing method of a semiconductor device, comprising:
forming a debonding material layer on a first release layer;
performing a first heating process to convert the debonding material layer from a liquid state to a solid state to form a first film structure;
forming an adhesive layer on a second release layer to form a second film structure;
assembling the first film structure and the second film structure into a film component;
attaching the film component to the process component;
performing a second heating process on the film component; and
performing a laser process to remove the debonding material layer.

2. The manufacturing method of the semiconductor device according to claim 1, wherein a temperature of the first heating process is lower than a temperature of the second heating process.

3. The manufacturing method of the semiconductor device according to claim 1, wherein a heating temperature range of the first heating process is between 60° C. and 200° C., and a heating time range of the first heating process is between 10 seconds and 120 seconds.

4. The manufacturing method of the semiconductor device according to claim 1, wherein a heating temperature range of the second heating process is between 200° C. and 300° C., and a heating time range of the second heating process is between 10 minutes and 60 minutes.

5. The manufacturing method of the semiconductor device according to claim 1, wherein an energy density of the laser process is between 1 watt and 6 watts.

6. The manufacturing method of the semiconductor device according to claim 1, wherein a wavelength of the laser process is 355 nanometers or 532 nanometers.

7. The manufacturing method of the semiconductor device according to claim 1, wherein the debonding material layer is formed by a micro-gravure process.

8. The manufacturing method of the semiconductor device according to claim 1, wherein attaching the film component to the process component further comprises:
attaching the debonding material layer and the first release layer to the process component through the adhesive layer after removing the second release layer;
performing a trimming process on the adhesive layer, the debonding material layer, and the first release layer; and
removing the first release layer.

9. The manufacturing method of the semiconductor device according to claim 8, wherein edges of the adhesive layer, edges of the debonding material layer, and edges of the process component are aligned after performing the trimming process.

10. The manufacturing method of the semiconductor device according to claim 1, wherein the process component is a square glass wafer.
